(19) United States
(12) Patent Application Publication
(10) Pub. No.: US 2014/0126152 A1
(43) Pub. Date: May 8, 2014

(54) CIRCUIT BOARD ASSEMBLY

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: CHIH-HAO YANG, New Taipei (TW); RONG YANG, Shenzhen (CN); CHENG HAO, Shenzhen (CN); ER-WEI LU, Shenzhen (CN)

(21) Appl. No.: 13/920,065

(22) Filed: Jun. 17, 2013

(30) Foreign Application Priority Data
Nov. 6, 2012 (CN) 2012104376096

(51) Int. Cl. H05K 7/20

(52) U.S. Cl. CPC H05K 7/20
USPC 361/704

(57) ABSTRACT

A circuit board assembly includes a circuit board, a heat dissipating apparatus, and a support member. The heat dissipating apparatus and the support member are attached to opposite sides of the circuit board. The support member helps the circuit board to support the heat dissipating apparatus. A plurality of mounting holes is defined in the circuit board. Each of the plurality of mounting holes includes a mounting portion and a limiting portion narrower than the mounting portion. The support member includes a plurality of taper-shaped mounting posts for engaging with the plurality of mounting holes. When the mounting post is engaged with the mounting portion, the support member is located at an unlatched position where the support member is disengageable from the circuit board. When the mounting post is engaged with the limiting portion, the support member is located at a latched position and secured to the circuit board.

### BACKGROUND

1. Technical Field

The present disclosure relates to a circuit board assembly.

2. Description of Related Art

A heat dissipating apparatus is mounted on a motherboard of a computer for dissipating heat generated by a central processing unit (CPU). Sometimes, the heat dissipating apparatus mounted on the circuit board is heavy and may distort the circuit board. Thus, a support member is attached to a backside of the circuit board to reinforce the circuit board. However, the support member is attached to the circuit board by screws. It's inconvenient to mount or dismount the support member.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of a circuit board assembly in accordance with an embodiment.

FIG. 2 is similar to FIG. 1, but viewed from another aspect.

FIG. 3 is an assembled view of the circuit board assembly of FIG. 1, and shows a plurality of mounting posts in an unlatched position.

FIG. 4 is similar to FIG. 3, but shows the plurality of mounting posts in a latched position.

FIG. 5 is an isometric view of a heat dissipating apparatus.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

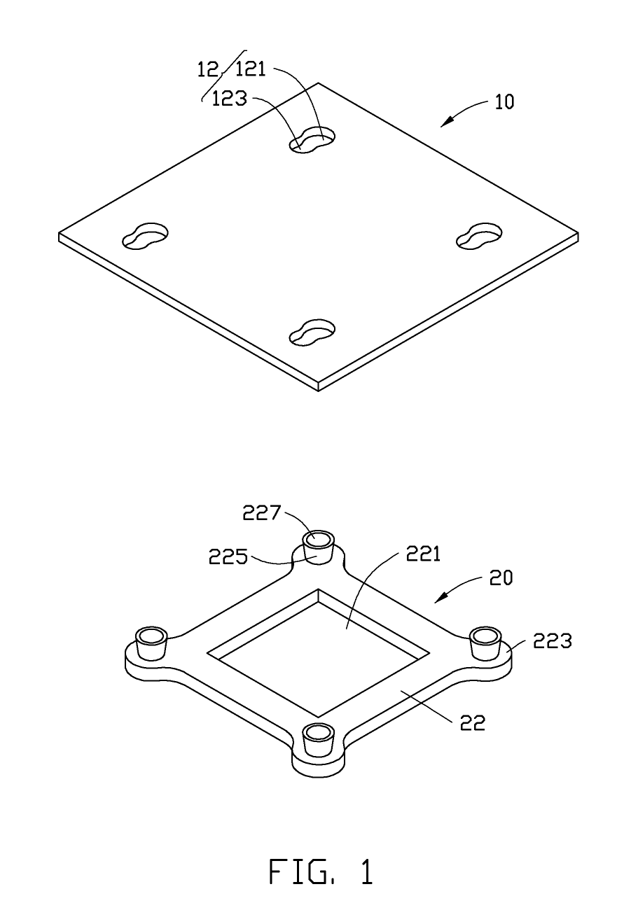

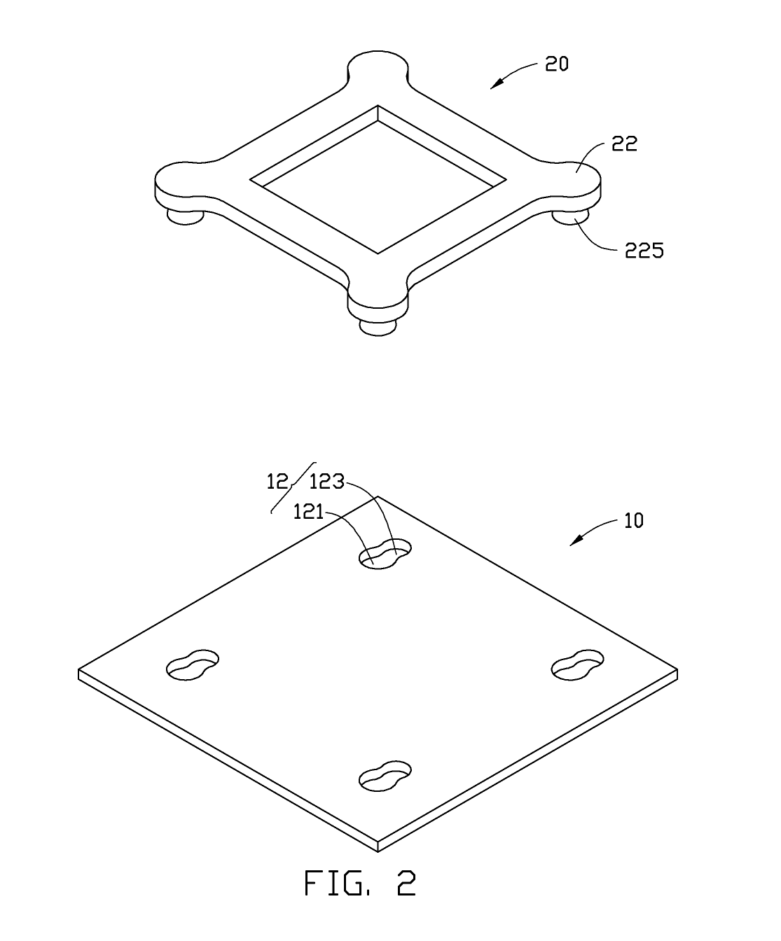

FIGS. 1 and 2 show an embodiment of a circuit board assembly. The circuit board assembly includes a circuit board 10 and a support member 20. A plurality of mounting holes 12 is defined in the circuit board 10. Each of the plurality of mounting holes 12 has a calabash shape and includes a mounting portion 121 and a limiting portion 123, connected to the mounting portion 121. A diameter of the mounting portion 121 is greater than that of the limiting portion 123.

The support member 20 includes a base plate 22. An opening 221 is defined in a central portion of the base plate 22. An arc-shaped protrusion 223 protrudes out from each corner of the base plate 22 along a diagonal line of the base plate 22. A mounting post 225 protrudes from each arc-shaped protrusion 223. A height of the mounting post 225 is greater than a thickness of the circuit board 10. The mounting post 225 has a taper shape. The mounting post 225 becomes gradually wider from bottom to top. A diameter of a lower end of the mounting post 225 is substantially equal to that of the limiting portion 123. A diameter of an upper end of the mounting post 225 is substantially equal to that of the mounting portion 121. The mounting post 225 is hollow and defines a hole 227 extending along an axial direction of the mounting post 225.

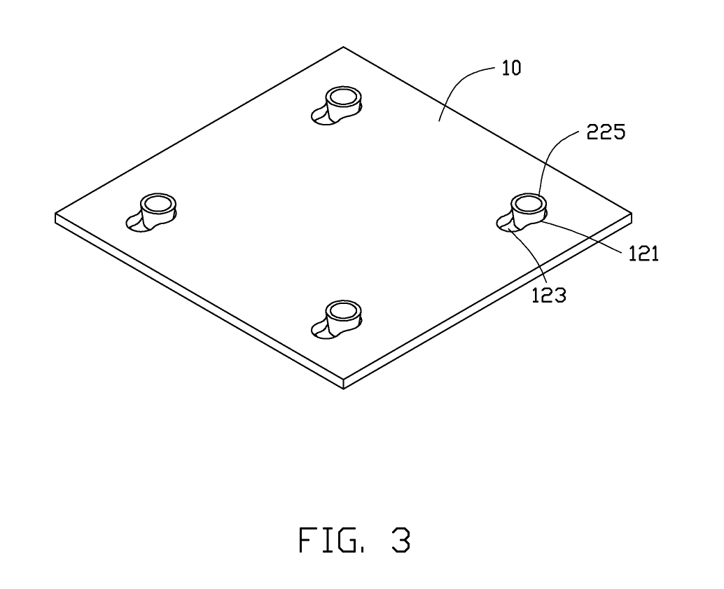

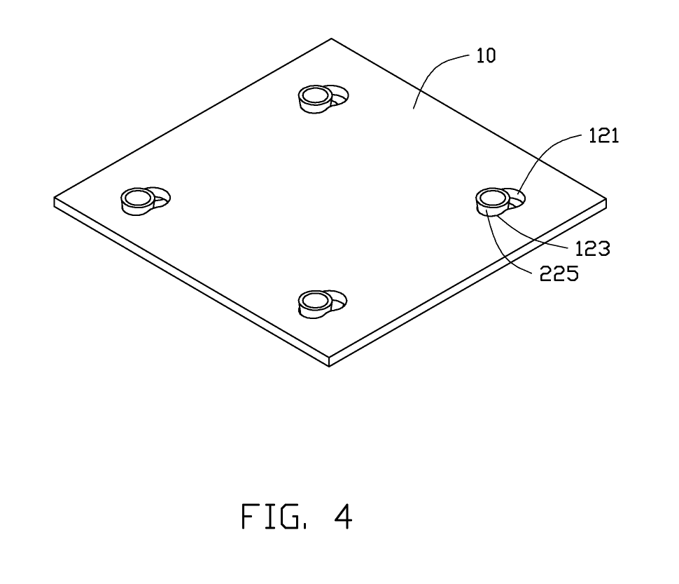

FIGS. 3 and 4 show that in assembly, the mounting post 225 is aligned with the mounting portion 121 and extends through the mounting portion 121, along a first direction, that is perpendicular to the circuit board 10. The lower end of the mounting post 225 is located in the mounting portion 121. The base plate 22 abuts against the circuit board 10. The support member 20 is moved towards the limiting portion 123 along a second direction, which is substantially perpendicular to the first direction. The lower end of the mounting post 225 is engaged with the limiting portion 123. The upper end of the mounting post 225 is wider than the limiting portion 123, to prevent the mounting post 225 disengaging away from the limiting portion 123 along a third direction, that is opposite to the first direction. Each of the plurality of mounting holes 12 includes a junction between the mounting portion 121 and the limiting portion 123. A width of the junction is slightly less than the diameter of the lower end of the mounting post 225, which prevents the mounting post 225 moving from the limiting portion 123 to the mounting portion 121 along a fourth direction that is opposite to the second direction. Thus, the support member 20 is secured to the circuit board 10.

To detach the support member 20 from the circuit board 10, the mounting post 225 is moved from the limiting portion 123 to the mounting portion 121 along the third direction. The junction between the limiting portion 123 and the mounting portion 121 is expanded and allows the mounting post 225 to move from the limiting portion 123 to the mounting portion 121. The mounting post 225 is moved away from the mounting portion 121 along the third direction. The support member 20 is detached from the circuit board 10.

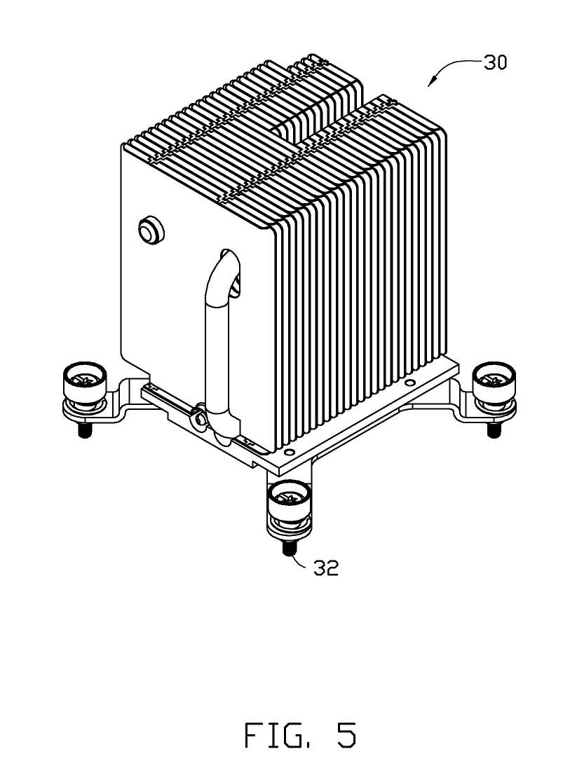

FIG. 5 shows that in one embodiment, a heat dissipating apparatus 30 can be mounted on the circuit board 10 and located above the support member 20. The heat dissipating apparatus 30 includes four fasteners 32. Each of the four fasteners 32 can be mounted in the hole 227. The support member 20 helps the circuit board 10 to support the heat dissipating apparatus 30 for preventing the heat dissipating apparatus 30 distorting the circuit board 10.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A circuit board assembly comprising:
a circuit board with a plurality of mounting holes, each of the plurality of mounting holes comprising a mounting portion and a limiting portion in communication with the mounting portion, and the limiting portion being narrower than the mounting portion;
a heat dissipating apparatus; and
a support member comprising a base plate and a plurality of taper-shaped mounting posts protruding from the base plate, for engaging with the plurality of mounting holes;
wherein the heat dissipating apparatus and the support member are attached to opposite sides of the circuit board, and the support member is capable of helping the circuit board to support the heat dissipating apparatus for preventing deformation of the circuit board; when each of the plurality of taper-shaped mounting posts is engaged with the mounting portion, the support member is located at an unlatched position, and the support member is disengageable from the circuit board in the unlatched position; when each of the plurality of taper-shaped mounting posts is engaged with the limiting portion, and the support member is located at a latched position and secured to the circuit board.

2. The circuit board assembly of claim 1, wherein a diameter of a lower end of each of the plurality of taper-shaped mounting posts is substantially equal to that of the limiting portion, and a diameter of an upper end of each of the plurality of taper-shaped mounting posts is substantially equal to the mounting portion.

3. The circuit board assembly of claim 2, wherein each of the plurality of mounting holes comprises a junction between the mounting portion and the limiting portion, and a width of the junction is slightly less than the diameter of the lower end of each of the plurality of mounting posts.

4. The circuit board assembly of claim 3, wherein a height of each of the plurality of taper-shaped mounting posts is greater than a thickness of the circuit board, and the plurality of taper-shaped mounting posts protrudes from the circuit board in the latched position.

5. The circuit board assembly of claim 1, wherein an opening is defined in a central portion of the base plate, an arc-shaped protrusion protrudes out from each corner of the base plate along a diagonal line of the base plate, and each of the plurality of taper-shaped mounting posts protrudes from the arc-shaped protrusion.

6. The circuit board assembly of claim 1, wherein each of the plurality of taper-shaped mounting posts is hollow and comprises a hole, the heat dissipating apparatus comprises a plurality of fasteners, and each of the plurality of fasteners is mounted in the hole.

7. The circuit board assembly of claim 1, wherein each of the plurality of taper-shaped mounting posts becomes gradually wider from bottom to top, and a bottom end of each of the plurality of taper-shaped mounting posts is connected to the base plate.

8. The circuit board assembly of claim 1, wherein each of the plurality of mounting holes has a calabash shape.

9. A circuit board assembly comprising:
a circuit board with at least one mounting hole, the at least one mounting hole comprises a mounting portion and a limiting portion connected to the mounting portion, and a diameter of the mounting portion is greater than that of the limiting portion; and
a support member comprising a base plate and at least one mounting post protruding from the base plate for engaging with the at least one mounting hole, a first diameter of a lower end of the at least one mounting post is substantially equal to the diameter of the limiting portion, and a second diameter of an upper end of the at least one mounting post is substantially equal the diameter of the mounting portion;
wherein when the at least one mounting post is engaged with the mounting portion, the support member is located at an unlatched position, and the support member is disengageable from the circuit board in the unlatched position; and when the at least one mounting post is engaged with the limiting portion, the support member is located at a latched position and secured to the circuit board.

10. The circuit board assembly of claim 9, further comprising a heat dissipating apparatus, wherein the heat dissipating apparatus and the support member are attached to opposite sides of the circuit board, and the support member is capable of helping the circuit board to support the heat dissipating apparatus for preventing deformation of the circuit board.

11. The circuit board assembly of claim 9, wherein the at least one mounting hole comprises a junction between the mounting portion and the limiting portion, and a width of the junction is slightly less than the diameter of the lower end of the at least one mounting post.

12. The circuit board assembly of claim 9, wherein a height of the at least one mounting post is greater than a thickness of the circuit board, and the at least one mounting post protrudes from the circuit board in the latched position.

13. The circuit board assembly of claim 9, wherein an arc-shaped protrusion protrudes out from each corner of the base plate along a diagonal line of the base plate, and the at least one mounting post protrudes from the arc-shaped protrusion.

14. The circuit board assembly of claim 10, wherein the at least one mounting post is hollow and comprises a hole, and the heat dissipating apparatus comprises a fastener mounted in the hole.

15. The circuit board assembly of claim 9, wherein the at least one mounting post has a taper-shaped and becomes gradually wider from bottom to top, and a bottom end of the at least one mounting post is connected to the base plate.

16. The circuit board assembly of claim 9, wherein the at lest one mounting hole has a calabash shape.
